(19) United States
(12) Patent Application Publication
(10) Pub. No.: US 2016/0284392 A1
(43) Pub. Date: Sep. 29, 2016

(54) MEMORY CELL, MEMORY DEVICE INCLUDING A PLURALITY OF MEMORY CELLS AND METHOD INCLUDING READ AND WRITE OPERATIONS AT A MEMORY CELL

(71) Applicant: GLOBALFOUNDRIES Inc., Grand Cayman (KY)

(72) Inventors: Stefan Block, Munich (DE); Juergen Dirks, Holzkirchen (DE); Herbert Johannes Preuthen, Dorfen (DE)

(21) Appl. No.: 14/666,420

(22) Filed: Mar. 24, 2015

(51) Int. Cl. G11C 11/419

(52) U.S. Cl. CPC G11C 11/419

(57) ABSTRACT

A memory cell includes an inverter loop. The inverter loop includes a plurality of inverter pairs, wherein an output of each inverter pair is connected to an input of a next inverter pair in the loop. Each inverter pair includes a first inverter and a second inverter. An input of the first inverter provides the input of the inverter pair. An output of the second inverter provides the output of the inverter pair. An output of the first inverter is connected to an input of the second inverter. The memory cell further includes a plurality of passgate transistor pairs. Each passgate transistor pair includes a first passgate transistor connected to the input of the first inverter of the inverter pair associated with the passgate transistor pair and a second passgate transistor connected to the input of the second inverter of the inverter pair associated with the passgate transistor pair.

### BACKGROUND OF THE INVENTION

1. Field of the Invention

Generally, the present disclosure relates to the field of integrated circuits and, more particularly, to integrated circuits including multi-port memory devices.

2. Description of the Related Art

Types of semiconductor memory include dynamic random access memory (DRAM) and static random access memory (SRAM). DRAM includes memory cells having a relatively simple structure, in particular memory cells wherein an amount of charge stored in a capacity is used to represent a bit of information. Due to the simple structure of DRAM cells, a high density of integration may be obtained. However, due to leakage currents in the capacities, DRAM typically requires constant refresh cycles to avoid a loss of information.

In SRAM devices, cross coupled inverters are used for storing information. In SRAM devices, refresh cycles need not be performed, and they typically allow a greater speed of operation than DRAM devices. However, SRAM includes memory cells which typically have a more complex structure than the memory cells of DRAM devices, which may limit the density of integration of SRAM devices that may be obtained.

SRAM devices include an array of SRAM cells, wherein each SRAM cell can store one bit of information. In addition to single port SRAM cells, types of SRAM cells that can be used in SRAM devices include dual port SRAM cells, wherein each SRAM cell has two read/write ports. The two read/write ports of each SRAM cell can allow simultaneous reading of the bit stored in the SRAM cell from both ports. Moreover, in some situations, simultaneous read and write operations can occur.

FIG. 1 shows a circuit diagram of a portion of a conventional memory device 100 including a dual port SRAM cell 101. The SRAM cell 101 includes a first inverter 102 and a second inverter 103. An output of the first inverter 102 is connected to an input of the second inverter 103, and an output of the second inverter 103 is connected to an input of the first inverter 102.

The SRAM cell 101 further includes a first passgate transistor pair 106 that includes passgate transistors 104, 105. Additionally, the SRAM cell 101 includes a second passgate transistor pair 110 that includes passgate transistors 108, 109.

The memory device 100 further includes a first wordline 107 and a second wordline 111, a first bitline pair 114 including a bitline 112 and an inverse bitline 113 and a second bitline pair 117 including a bitline 115 and an inverse bitline 116.

The passgate transistor 104 can be connected between the bitline 112 and the input of the inverter 102. The passgate transistor 105 can be connected between the inverse bitline 113 and the input of the inverter 103. Gate electrodes of the passgate transistors 104, 105 of the first passgate transistor pair 106 can be connected to the first wordline 107. By applying a passgate transistor turn-on voltage to the first wordline 107, the passgate transistors 104, 105 of the first passgate transistor pair 106 can be switched into an electrically conductive state so that an electrical connection of the bitline 112 and the inverse bitline 113 of the first bitline pair 114 with the inverters 102, 103 of the SRAM cell 101 is provided.

The passgate transistor 108 can be connected between the input of the inverter 102 and the bitline 115. The passgate transistor 109 can be connected between the input of the inverter 103 and the inverse bitline 116. Gate electrodes of the passgate transistors 108, 109 of the second passgate transistor pair 110 can be connected to the second wordline 111. By applying the passgate transistor turn-on voltage to the second wordline 111, the passgate transistors 108, 109 can be switched into an electrically conductive state so that an electrical connection of the bitline 115 and the inverse bitline 116 of the second bitline pair 117 with the inverters 102, 103 of the SRAM cell 101 is provided.

The connections of the passgate transistors 104, 105 of the first passgate transistor pair 106 to the bitline 112 and the inverse bitline 113 of the first bitline pair 114, and the connections of the gate electrodes of the passgate transistors 104, 105 to the first wordline 107 provide a first read/write port of the SRAM cell 101.

The connections of the passgate transistors 108, 109 of the second passgate transistor pair 110 to the bitline 115 and the inverse bitline 116 of the second bitline pair 117, and the connections of the gate electrodes of the passgate transistors 108, 109 to the second wordline 111 provide a second read/write port of the SRAM cell 101.

When the passgate transistors 104, 105, 108, 109 are in their off-state, the inverters 102, 103 can be in one of two states, wherein each of the states represents a bit of information stored in the SRAM cell 101. In the first state, the output of the first inverter 102 is at a high voltage (typically, a few volts or less), and the output of the second inverter 103 is at a low voltage (typically, a mass potential of the memory device 100). In the second state, the output of the first inverter 102 is at the low voltage, and the output of the second inverter 103 is at the high voltage.

For reading the bit of data stored in the SRAM cell 101 and for writing a bit of data into the SRAM cell 101, both the first read/write port provided by the connections of the SRAM cell 101 to the first wordline 107 and the first bitline pair 114 and the second read/write port provided by the connections of the SRAM cell 101 to the second bitline 111 and the second bitline pair 117 can be used.

For reading the bit of data, the bitline and the inverse bitline of the bitline pair 114 or the bitline pair 117, respectively, can be pre-charged to the high voltage. Then, the passgate transistor turn-on voltage can be applied to the first wordline 107 (when the first read/write port is used) or the second wordline 111 (when the second read/write port is used) for switching the passgate transistors of the passgate transistor pair 106 or the passgate transistors of the passgate transistor pair 110 into the electrically conductive on-state. Then, a voltage difference that is representative of the state of the SRAM cell 101 can be measured between the bitline and the inverse bitline of the bitline pair 114 or the bitline pair 117, respectively.

For writing a bit of data to the SRAM cell 101, a voltage difference can be applied between the bitline and the inverse bitline of the bitline pair 114 or the bitline pair 117, respectively. Depending on the value of the bit of data to be written into the SRAM cell 101, the bitline can be maintained at the high voltage and the inverse bitline can be maintained at the low voltage, or the bitline can be maintained on the low voltage and the inverse bitline can be maintained at the high voltage. Then, the passgate transistor turn-on voltage can be applied to the first wordline 107 (when the first read/write port is used) or the second wordline 111 (when the second read/write port is used) for switching the passgate transistors of the passgate transistor pair 106 or the passgate transistors of the passgate transistor pair 110 into the on-state so that the voltage difference between the bitline and the inverse bitline of the bitline pair 114 or 117, respectively, is applied to the inputs of the inverters 102, 103.

The conventional memory device 100 described above can have some issues associated therewith. When the two read/write ports of the SRAM cell 101 are used at the same time, the passgate transistor turn-on voltage is applied both to the first wordline 107 and the second wordline 111, and all of the passgate transistors 104, 105, 108, 109 are substantially simultaneously switched into the electrically conductive on-state. Thus, the passgate transistors 104 and 108 establish an electrical connection between the bitline 112 of the bitline pair 114 and the bitline 115 of the bitline pair 117. The passgate transistors 105, 109 provide an electrical connection between the inverse bitline 113 of the bitline pair 114 and the inverse bitline 116 of the bitline pair 117. Thus, electric currents can flow between the bitlines 112, 115 and between the inverse bitlines 113, 116. In some cases, in particular in memory devices that are manufactured in accordance with advanced technology nodes (for example, the 28 nm technology node or below), this can lead to a data loss in the memory cell 101 or in other memory cells (not shown) of the memory device 100.

In view of the situation described above, the present disclosure provides memory cells, memory devices and methods wherein the above-mentioned issue is overcome substantially completely or at least partially.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative memory cell disclosed herein includes an inverter loop. The inverter loop includes a plurality of inverter pairs connected in a loop, wherein an output of each inverter pair is connected to an input of a next inverter pair in the loop. Each inverter pair includes a first inverter and a second inverter. An input of the first inverter provides the input of the inverter pair. An output of the second inverter provides the output of the inverter pair. An output of the first inverter is connected to an input of the second inverter. The memory cell further includes a plurality of passgate transistor pairs. Each inverter pair is associated with one of the plurality of passgate transistor pairs. Each passgate transistor pair includes a first passgate transistor connected to the input of the first inverter of the inverter pair associated with the passgate transistor pair and a second passgate transistor connected to the input of the second inverter of the inverter pair associated with the passgate transistor pair.

An illustrative memory device disclosed herein includes a plurality of memory cells. Each memory cell includes an inverter loop and a plurality of passgate transistor pairs. The inverter loop includes a plurality of inverter pairs connected in a loop. An output of each inverter pair is connected to an input of a next inverter pair in the loop. Each inverter pair includes a first inverter and a second inverter. An input of the first inverter provides the input of the inverter pair. An output of the second inverter provides the output of the inverter pair. An output of the first inverter is connected to an input of the second inverter. Each inverter pair is associated with one of the plurality of passgate transistor pairs. Each passgate transistor pair includes a first passgate transistor and a second passgate transistor. The memory device further includes a plurality of wordlines and a plurality of bitline pairs. For each memory cell, each passgate transistor pair of the memory cell is associated with one of the wordlines. For each passgate transistor pair, a gate electrode of the first passgate transistor and a gate electrode of the second passgate transistor are connected to the wordline associated with the passgate transistor pair. Each bitline pair includes a bitline and an inverse bitline. For each memory cell, each passgate transistor pair is associated with one of the bitline pairs. For each passgate transistor pair, the first passgate transistor is connected between the bitline of the bitline pair associated with the passgate transistor pair and the input of the first inverter of the inverter pair associated with the passgate transistor pair. The second passgate transistor is connected between the inverse bitline of the bitline pair associated with the passgate transistor pair and the input of the second inverter of the inverter pair associated with the passgate transistor pair.

An illustrated method disclosed herein includes providing a memory device. The memory device includes a memory cell, a plurality of wordlines and a plurality of bitline pairs. The memory cell includes an inverter loop and a plurality of passgate transistor pairs. The inverter loop includes a plurality of inverter pairs connected in a loop, wherein an output of each inverter pair is connected to an input of a next inverter pair in the loop. Each inverter pair includes a first inverter and a second inverter. An input of the first inverter provides the input of the inverter pair. An output of the second inverter provides the output of the inverter pair. An output of the first inverter is connected to an input of the second inverter. Each inverter pair is associated with one of the plurality of passgate transistor pairs. Each passgate transistor pair includes a first passgate transistor and a second passgate transistor. Each of the wordlines is associated with one of the passgate transistor pairs, wherein, for each passgate transistor pair, a gate electrode of the first passgate transistor and a gate electrode of the second passgate transistor are connected to the wordline associated with the passgate transistor pair. Each bitline pair includes a bitline and an inverse bitline. Each of the bitline pairs is associated with one of the passgate transistor pairs. For each passgate transistor pair, the first passgate transistor is connected between the bitline of the bitline pair associated with the passgate transistor pair and the input of the first inverter of the inverter pair associated with the passgate transistor pair. The second passgate transistor is connected between the inverse bitline of the bitline pair associated with the passgate transistor pair and the input of the second inverter of the inverter pair associated with the passgate transistor pair. The method further includes performing a read operation at the memory cell. The read operation includes applying a passgate transistor turn-on voltage to a first wordline of the plurality of wordlines and measuring a voltage difference between the bitline and the inverse bitline of a first bitline pair of the plurality of bitline pairs. The first wordline and the first bitline pair are associated with a first passgate transistor pair of the plurality of passgate transistor pairs. A write operation is performed at the memory cell. The write operation includes applying a passgate transistor turn-on voltage to a second wordline of a plurality of wordlines, applying a first write voltage representing a bit of data to the bitline of a second bitline pair of the plurality of bitline pairs and applying a second write voltage representing an inverse of the bit of data to the inverse bitline of the second bitline pair. The second wordline and the second bitline pair are associated with a second passgate transistor pair of the plurality of passgate transistor pairs.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a conventional memory device including a dual port memory cell;

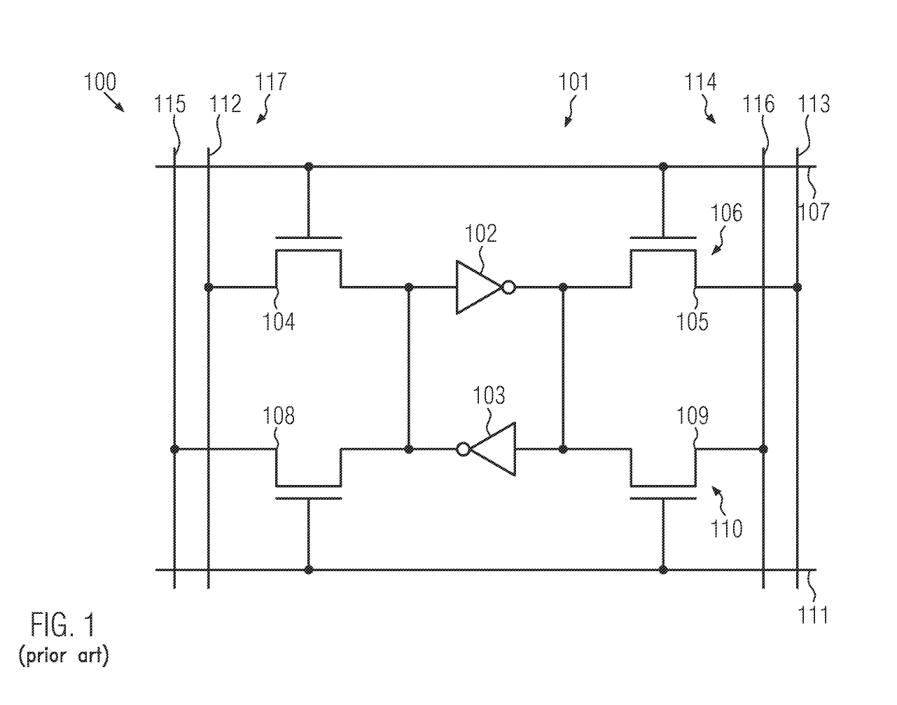

FIG. 2 schematically illustrates a memory device according to an embodiment;

FIG. 3 schematically illustrates a portion of the memory device of FIG. 2 including a memory cell;

FIG. 4 schematically illustrates an inverter in the memory cell shown in FIG. 3; and

FIG. 5 schematically illustrates a portion of a memory device according to an embodiment including a memory cell.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

In embodiments disclosed herein, a two-port memory cell is provided that includes four inverters. This can allow an isolation of the passgate transistors from each other. So, even if the wordlines connected to the two read/write ports of the memory cell are active at the same time, there is no electrical connection between the bitlines and the inverse bitlines connected to the memory cell. If data are written at the same time to both ports of the memory cell, the data in the memory cell can be unknown and not predictable. However, it is safe to substantially simultaneously write a bit of data to one of the read/write ports and read the bit of data from the other read/write port without a data loss in any memory cell of the memory device. In some embodiments, the memory cell can include twelve transistors, which is greater than the number of transistors in the conventional memory cell 101 described above, which includes eight transistors, so that a greater area in an integrated circuit can be required for the memory device. However, this additional area can be acceptable in view of the greater safety of operation and the lower risk of data loss.

In other embodiments, memory cells including a number of read/write ports greater than two, for example three-port or four-port memory cells, are provided, wherein two inverters per additional read/write port are added into the inverter loop.

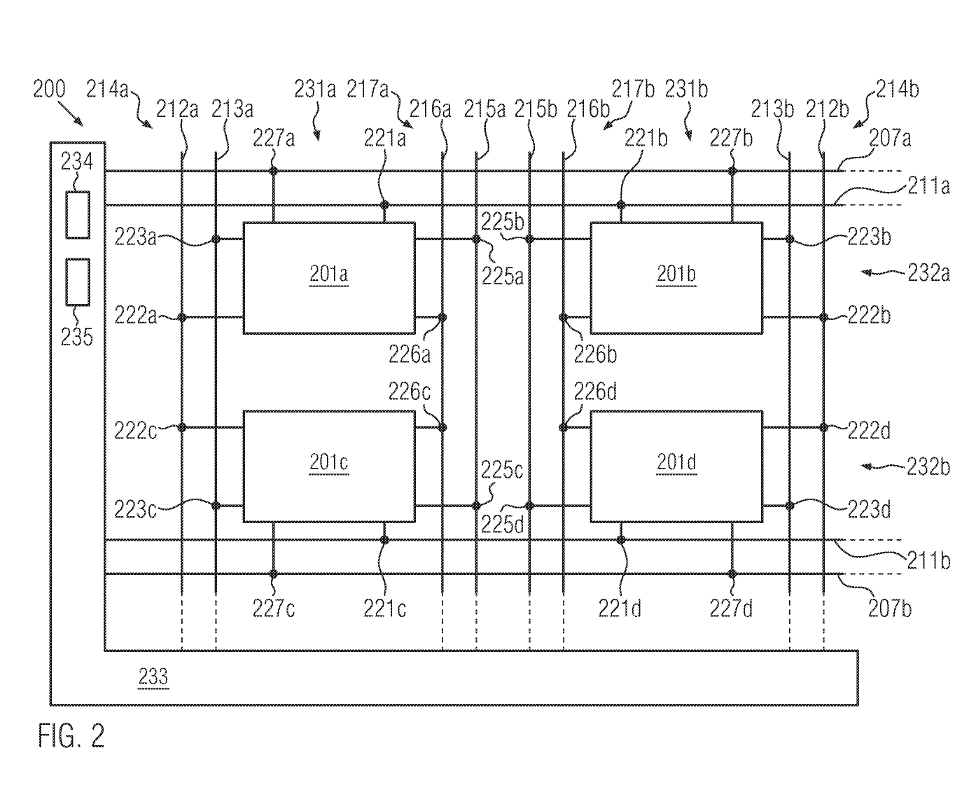

FIG. 2 shows a schematic circuit diagram of a memory device 200 according to an embodiment. The memory device 200 includes a plurality of memory cells 201a, 201b, 201c, 201d that form an array of memory cells having columns 231a, 231b and rows 232a, 232b. Each of the memory cells 201a, 201b, 201c, 201d is arranged in one of the columns 231a, 231b and one of the rows 232a, 232b of the array of memory cells. Memory cell 201a is in column 231a and row 232a, memory cell 201b is in column 231b and row 232a, memory cell 201c is in column 231a and row 232b and memory cell 201d is in column 231b and row 232b. Each of the memory cells 201a, 201b, 201c, 201d of the memory device 200 can be a two-port SRAM memory cell having two read/write ports, wherein each of the read/write ports can be used for reading a bit of data stored in the memory cell and for writing a bit of data to the memory cell.

A first read/write port of the memory cell 201a is provided by a bitline connection 222a, an inverse bitline connection 223a and a wordline connection 227a. A second read/write port of the memory cell 201a is provided by a bitline connection 225a, an inverse bitline connection 226a and a wordline connection 221a. Similarly, each of the memory cells 201b, 201c, 201d has a first read/write port and a second read/write port, wherein each of the read/write ports includes a bitline connection, an inverse bitline connection and a wordline connection. In FIG. 2, the bitline connections, inverse bitline connections and wordline connections of the first read/write ports of the memory cells 201b, 201c, 201d are denoted by reference numerals 222, 223 and 227, respectively, followed by a letter b, c or d, respectively, indicating the memory cell. The bitline connections, inverse bitline connections and wordline connections of the second read/write ports of the memory cells 201b, 201c, 201d are denoted by reference numerals 225, 226 and 221, respectively, followed by a letter b, c or d, respectively, indicating the memory cell.

The memory device 200 further includes a plurality of wordlines 207a, 207b, 211a, 211b. A subset of the wordlines including wordlines 207a, 211a is associated with the row 232a of the array of memory cells, and another subset of the wordlines including wordlines 207b, 211b is associated with the row 232b. The number of wordlines associated with each of the rows 232a, 232b is equal to the number of read/write ports of each of the memory cells 201a, 201b, 201c, 201d, which, in the embodiment illustrated in FIG. 2, is two.

The wordline connections 227a, 227b of the first read/write ports of the memory cells 201a, 201b in the row 232a of the array of memory cells are connected to the wordline 207a, and the wordline connections 221a, 221b of the second read/write ports of the memory cells 201a, 201b are connected to wordline 211a. The wordline connections 227c, 227d of the first read/write ports of the memory cells 201c, 201d in the row 232b of the array of memory cells are connected to the wordline 207b, and the wordline connections 221c, 221d of the second read/write ports of the memory cells 201c, 201d are connected to the wordline 211b.

The memory device 200 further includes a plurality of bitline pairs 214a, 217a, 214b, 217b. Bitline pairs 214a, 217a are associated with the column 231a of the array of memory cells, and bitline pairs 214b, 217b are associated with the column 231b. The number of bitline pairs associated with each of the columns 231a, 231b is equal to the number of read/write ports of each of the memory cells 201a, 201b, 201c, 201d, which, in the embodiment illustrated in FIG. 2, is two.

Each of the bitline pairs 214a, 217a, 214b, 217b includes a bitline and an inverse bitline. In particular, bitline pair 214a includes bitline 212a and inverse bitline 213a, bitline pair 217a includes bitline 215a and inverse bitline 216a, bitline pair 214b includes bitline 212b and inverse bitline 213b and bitline pair 217b includes bitline 215b and inverse bitline 216b. The bitline connections 222a, 222c and inverse bitline connections 223a, 223c of the first read/write ports of the memory cells 201a, 201c in the column 231a are connected to the bitline 212a and the inverse bitline 213a, respectively, of the bitline pair 214a. The bitline connections 225a, 225c and inverse bitline connections 226a, 226c of the second read/write ports of the memory cells 201a, 201c in the column 231a are connected to the bitline 215a and the inverse bitline 216a, respectively, of the bitline pair 217a. Similarly, the bitline connections 222b, 222d and inverse bitline connections 223b, 223d of the first read/write ports of the memory cells 201b, 201d in the column 231b are connected to the bitline 212b and the inverse bitline 213b, respectively, of the bitline pair 214b, and the bitline connections 225b, 225d and inverse bitline connections 226b, 226d of the second read/write ports of the memory cells 201b, 201d in the column 231b are connected to the bitline 215b and the inverse bitline 216b, respectively.

In addition to the components shown in FIG. 2, the array of memory cells can include further columns and rows of memory cells and further wordlines and bitline pairs having features corresponding to those of the components shown in FIG. 2. As shown in FIG. 2, the arrangement of components in alternating columns of the array of memory cells can be mirror symmetrical with respect to each other, with an axis of symmetry parallel to the vertical direction in the plane of drawing of FIG. 2. The arrangement of components in alternating rows of the array of memory cells can also be mirror symmetrical with respect to each other, with an axis of symmetry that is parallel to the horizontal direction in the plane of drawing of FIG. 2.

The bitlines 212a, 212b, 215a, 215b, inverse bitlines 213a, 213b, 216a, 216b and the wordlines 207a, 207b, 211a, 211b can be connected to a control circuit 233 including a read circuit 234 and a write circuit 235 for reading bits of data from the memory cells 201a, 201b, 201c, 201d and writing bits of data to the memory cells 201a, 201b, 201c, 201d. Features of the control circuit 233, in particular features of the read circuit 234 and the write circuit 235, can correspond to features of control circuits of conventional multi-port SRAM memory devices.

As will be described in more detail below, the present disclosure is not limited to embodiments wherein each of the memory cells 201a, 201b, 201c, 201d is a two-port memory cell. In other embodiments, a greater number of read/write ports per memory cells can be provided, for example three read/write ports, four read/write ports or an even greater number of read/write ports, wherein each of the read/write ports includes a bitline connection, an inverse bitline connection and a wordline connection. In such embodiments, a number of wordlines being equal to the number of read/write ports of the memory cells 201a, 201b, 201c, 201d can be provided in each of the rows 232a, 232b of the array of memory cells, and a number of bitline pairs being equal to the number of read/write ports of the memory cells 201a, 201b, 201c, 201d can be provided in each of the columns 231a, 231b of the array of memory cells.

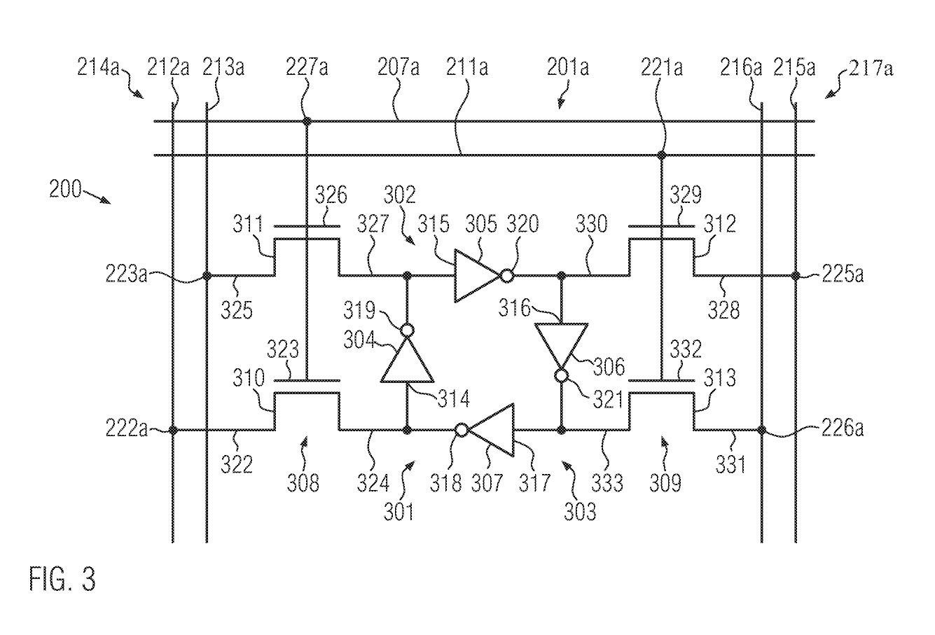

FIG. 3 shows a circuit diagram of a portion of the memory device 200 illustrating components of the memory cell 201a. Features of the memory cells 201b, 201c, 201d and further memory cells in the array of memory cells of the memory device 200 can correspond to features of the memory cell 201a. Hence, a detailed description thereof will be omitted.

The memory cell 201a includes an inverter loop 301. The inverter loop 301 includes two inverter pairs 302, 303. The number of inverter pairs of the memory cell 201a corresponds to the number of read/write ports of the memory cell 201a. Each of the inverter pairs 302, 303 is associated with one of the read/write ports of the memory cell 201a, wherein the inverter pair 302, being a first inverter pair, is associated with the first read/write port including bitline connection 222a, inverse bitline connection 223a and wordline connection 227a, and the inverter pair 303, being a second inverter pair, is associated with the second read/write port including bitline connection 225a, inverse bitline connection 226a and wordline connection 221a.

Each of the inverter pairs 302, 303 includes a first inverter and a second inverter. In FIG. 3, reference numeral 304 denotes the first inverter of the inverter pair 302, reference numeral 305 denotes the second inverter of the inverter pair 302, reference numeral 306 denotes the first inverter of the inverter pair 303 and reference numeral 307 denotes the second inverter of the inverter pair 303.

The inverter pair 302 has an input that is provided by an input 314 of the first inverter 304 of the inverter pair 302 and an output provided by an output 320 of the second inverter 305 of the inverter pair 302. An output 319 of the first inverter 304 is connected to an input 315 of the second inverter 305.

Similarly, the second inverter pair 303 has an input provided by an input 316 of the first inverter 306 of the inverter pair 303 and an output provided by an output 318 of the second inverter 307 of the inverter pair 303. An output 321 of the first inverter 306 is connected to an input 317 of the second inverter 307.

The output of the inverter pair 302, being provided by the output 320 of the second inverter 305 of the inverter pair 302, is connected to the input of the inverter pair 303, being provided by the input 316 of the first inverter 306 of the inverter pair 303. The output of the inverter pair 303, being provided by the output 318 of the second inverter 307 of the inverter pair 303, is connected to the input of the inverter pair 302, being provided by the input 314 of the first inverter 304 of the inverter pair 302. Thus, the inverter pairs 302, 303 are connected in a loop, wherein the output of each of the inverter pairs 302, 303 is connected to an input of a next one of the inverter pairs 302, 303 in the inverter loop 301. For the inverter pair 302, inverter pair 303 is the next inverter pair in the inverter loop 301 and, for the inverter pair 303, the inverter pair 302 is the next inverter pair in the inverter loop 301.

The inverter loop 301 can have two states which can represent a bit of information stored in the memory cell 201. In the first state of the inverter loop 301, the outputs 319, 321 of the first inverters 304, 306 of the inverter pairs 302, 303 are at a low voltage (typically the mass potential of the memory device), and the outputs 320, 318 of the second inverters 305, 307 of the inverter pairs 302, 303 are at a high voltage (typically a few volt or less). In the second state, the outputs of the first inverters 304, 306 are at the high voltage, and the outputs of the second inverters 305, 307 are at the low voltage.

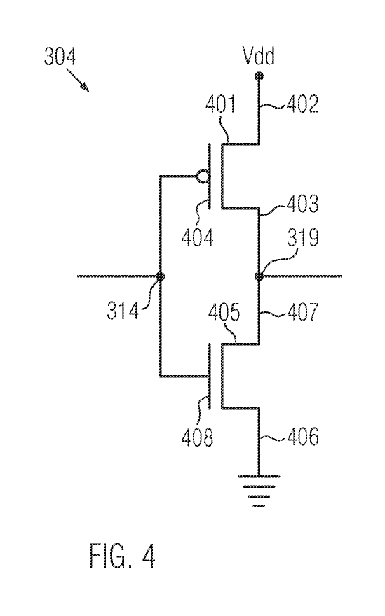

FIG. 4 shows a circuit diagram of the first inverter 304 of the inverter pair 302. The other inverters 305, 306, 307 of the inverter pairs 302, 303 in the inverter loop 301 can have features corresponding to those of the inverter 304. The inverter 304 includes a pull-up transistor 401, being a P-channel field effect transistor, and a pull-down transistor 405, being an N-channel field effect transistor. The pull-up transistor 401 is electrically connected between a positive power supply voltage Vdd and the output 319 of the inverter 304, wherein a source region 402 of the pull-up transistor 401 is connected to the power supply voltage Vdd, and a drain region 403 of the pull-up transistor 401 is connected to the output 319. The pull-down transistor 405 is connected between mass potential and the output 319 of the inverter 304, wherein a source region 406 of the pull-down transistor 405 is connected to mass potential, and a drain region 407 of the pull-down transistor 405 is connected to the output 319. A gate electrode 405 of the pull-up transistor 401 and a gate electrode 408 of the pull-down transistor 405 are connected to the input 314 of the inverter 304. Each of the pull-up transistor 401 and the pull-down transistor 405 can include a gate insulation layer, wherein the gate insulation layers of the pull-up transistor 401 and the pull-down transistor 405 provide an electrical insulation between the input 314 and the output 319 of the inverter 304.

Referring back to FIG. 3, the memory cell 201a further includes a first passgate transistor pair 308 including passgate transistors 310, 311 and a second passgate transistor pair 309 including passgate transistors 312, 313. The passgate transistors 310, 311, 312, 313 can be N-channel field effect transistors, and they can be switched into an electrically conductive on-state by applying a passgate transistor turn-on voltage, which can be the high voltage to gate electrodes thereof, and they can be in an electrically substantially non-conductive off-state wherein only leakage currents can flow through the passgate transistors 310, 311, 312, 313 when the low voltage is applied to their gate electrodes.

Each of the inverter pairs 302, 303 is associated with one of the passgate transistor pairs 308, 309. In particular, the inverter pair 302 can be associated with the passgate transistor pair 308 and the inverter pair 303 can be associated with the passgate transistor pair 309.

The first passgate transistor 310 of the passgate transistor pair 308 is connected between the bitline connection 221a and the input 314 of the first inverter 304 of the inverter pair 302, wherein a first source/drain region 322 of the passgate transistor 310 is connected to the bitline connection 222a, and a second source/drain region 324 of the passgate transistor 310 is connected to the input 314 of the first inverter 304 of the inverter pair 302. Additionally, the source/drain region 324 is connected to the output 318 of the second inverter 307 of the inverter pair 303 that is connected to the input 314.

The second passgate transistor 311 of the passgate transistor pair 308 is connected between the inverse bitline connection 223a and the input 315 of the second inverter 305 of the inverter pair 302. A first source/drain region 325 of the second passgate transistor 311 is connected to the inverse bitline connection 223a and a second source/drain region 327 of the passgate transistor 311 is connected to the input 315 of the second inverter 305 of the inverter pair 302. Additionally, the source/drain region 327 is connected to the output 319 of the first inverter 304 of the inverter pair 302 that is connected to the input 315. Gate electrodes 323, 326 of the passgate transistors 310, 311 of the first passgate transistor pair 308 are connected to the wordline connection 227a.

The passgate transistors 310, 311 of the first passgate transistor pair 308 can be used for reading data from the memory cell 201a and for writing data to the memory cell 201a via the first read/write port of the memory cell 201a that includes the bitline connection 222a, the inverse bitline connection 223a and the wordline connection 227a.

For reading the bit of data by means of the first read/write port, the bitline 212a and the inverse bitline 213a of the first bitline pair 214a can be pre-charged to the high voltage. Thereafter, the bitline 212a and the inverse bitline 213a can be left electrically floating, and the passgate transistor turn-on voltage can be applied to the wordline 207a, so that the passgate transistor turn-on voltage is applied to the gate electrodes 323, 326 of the passgate transistors 310, 311 and the passgate transistors 310, 311 are switched into the electrically conductive on-state. Thereafter, a voltage difference between the bitline 212a and the inverse bitline 213a can be measured, wherein the voltage difference depends on the state of the inverter loop 301. These actions can be performed by the read circuit 234 of the control circuit 233 schematically shown in FIG. 2.

For writing a bit of data to the memory cell 201a by means of the first read/write port, voltages in accordance with the bit of data to be written can be applied to the bitline 212a and the inverse bitline 213a of the first bitline pair 214a. Depending on the value of the bit of data to be written, a high voltage or a low voltage can be applied to the bitline 212a. The voltage applied to the inverse bitline 213a is inverse to the voltage applied to the bitline 212a, wherein a high voltage is applied to the inverse bitline 213a when a low voltage is applied to the bitline 212a, and a low voltage is applied to the inverse bitline 213a when a high voltage is applied to the bitline 212a. Additionally, the passgate transistor turn-on voltage can be applied to the wordline 207a so that the passgate transistors 310, 311 of the first passgate transistor pair 308 are switched into the electrically conductive on-state and the voltages applied to the bitline 212a and the inverse bitline 213a are applied to the inputs of the first inverter 304 and the second inverter 305 of the inverter pair 302. Since the output of the first inverter pair 302 is applied to the input of the second inverter pair 303, the inverter loop 301 can obtain a state in accordance with the voltages applied to the bitlines 212a, 213a. These steps can be performed by the write circuit 235 provided in the control circuit 233 of the memory device 200 that is schematically shown in FIG. 2.

The first passgate transistor 312 of the second passgate transistor pair 309 is connected between the bitline connection 225a and the input 316 of the first inverter 306 of the inverter pair 303, wherein a first source/drain region 328 of the first passgate transistor 312 is connected to the bitline connection 225a, and a second source/drain region 330 of the first passgate transistor 312 is connected to the input 316 of the first inverter 306.

The second passgate transistor 313 of the second passgate transistor pair 309 can be connected between the inverse bitline connection 226a and the input 317 of the second inverter 307 of the inverter pair 303, wherein a first source/drain region 331 of the second passgate transistor 313 is connected to the inverse bitline connection 226a and a second source/drain region 333 of the second passgate transistor 313 is connected to the input 317 of the second inverter 307. Gate electrodes 329, 332 of the passgate transistors 312, 313 of the second passgate transistor pair 309 can be connected to the wordline connection 221a.

The passgate transistors 312, 313 of the second passgate transistor pair 309 can be used for reading the bit of data stored in the memory cell 201a and writing a bit of data to the memory cell 201a via the second read/write port of the memory cell 201a that includes the bitline connection 225a, the inverse bitline connection 226a and the wordline connection 221a. This can be done by techniques corresponding to those for reading the bit of data stored in the memory cell 201a and writing a bit of data to the memory cell 201a via the first read/write port described above wherein, however, the second wordline 211a and the second bitline pair 217a are used instead of the first wordline 207a and the first bitline pair 214a. Actions for reading the bit of data stored in the memory cell 201a and for writing a bit of data to the memory cell 201a via the second read/write port can be performed by the read circuit 234 and the write circuit 235 of the control circuit 233 schematically shown in FIG. 2.

In some embodiments, writing a bit of data to the memory cell 201a via one of the read/write ports and reading the bit of data from the memory cell 201a via the other read/write port can be performed at a same time, wherein a duration of the read operation overlaps a duration of the write operation. In particular, the read operation and the write operation can be performed substantially simultaneously. In doing so, all of the passgate transistors 310, 311, 312, 213 can be in their electrically conductive on-state at the same time. However, since, due to the presence of the inverters 304, 305, 306, 307, there is no direct electrical connection between any two of the source/drain regions 324, 327, 330, 333 of the passgate transistors 310, 311, 312, 313, this does not lead to an electric shortcut connection between the bitlines 212a, 215a or between the inverse bitlines 213a, 216a.

In some embodiments, writing a bit of data to the memory cell 201a via the first read/write port and writing a bit of data to the memory cell 201a via the second read/write port can also be performed simultaneously. In this case, the inverters 304, 305, 306, 307 can also provide an electrical insulation between the bitlines 212a, 216a and between the inverse bitlines 213a, 215a.

As already mentioned above, the present disclosure is not limited to embodiments wherein the memory cells of the array of memory cells are two-port memory cells. In other embodiments, a greater number of read/write ports can be provided. For providing additional read/write ports, an additional passgate transistor pair associated with the additional read/write port and an additional inverter pair associated with the additional passgate transistor pair can be provided in each of the memory cells for each of the additional read/write port. The inverter pairs can be included into the inverter loops of the memory cell. Furthermore, an additional bitline pair can be provided in each of the columns of the array of memory cells, and an additional wordline can be provided in each of the array of memory cells for each of the additional read/write ports.

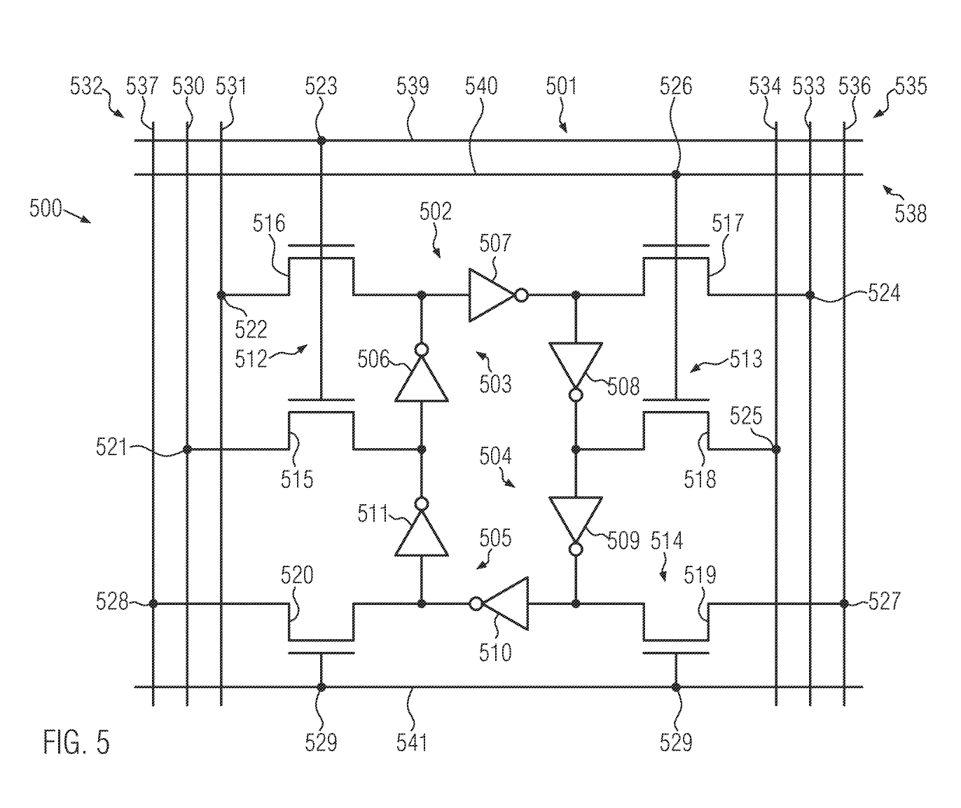

FIG. 5 shows a circuit diagram of a portion of a memory device 500 that includes a three-port memory cell 501. The memory cell 501 includes an inverter loop 502 that includes a first inverter pair 503, a second inverter pair 504 and a third inverter pair 505. Each of the inverter pairs 503, 504, 505 includes a first inverter and a second inverter. In FIG. 5, reference numerals 506, 508 and 510 denote the first inverters of the inverter pairs 503, 504 and 505, respectively, and reference numerals 507, 509 and 511 denote the second inverters of the inverter pairs 503, 504 and 505, respectively. The inverter pairs 503, 504, 505 are connected in a loop, wherein an output of each inverter pair is connected to an input of the next inverter pair in the loop.

The first inverter pair 503 is associated with a first passgate transistor pair 512. The passgate transistor pair 512 includes a first passgate transistor 515 that is connected between a bitline connection 521 and an input of the first inverter 506 of the inverter pair 503 and a second passgate transistor 516 that is connected between an inverse bitline connection 522 and an input of the second inverter 507 of the first inverter pair 503. Gate electrodes of the passgate transistors 515, 516 can be connected to a wordline connection 523. The bitline connection 521, the inverse bitline connection 522 and the wordline connection 523 provide a first read/write port of the memory cell 501, and they can be connected to a bitline 530 and an inverse bitline 531 of a first bitline pair 532 and a first wordline 539.

The second inverter pair 504 is associated with a second passgate transistor pair 513 including a first passgate transistor 517 and a second passgate transistor 518. The first passgate transistor 517 is connected between a bitline connection 524 and an input of the first inverter 508 of the second inverter pair 504, and the passgate transistor 518 is connected between an inverse bitline connection 525 and an input of the second inverter 509 of the inverter pair 504. Gate electrodes of the passgate transistors 517, 518 are connected to a wordline connection 526. The bitline connection 524, the inverse bitline connection 525 and the wordline connection 526 provide a second read/write port of the memory cell 501 that can be addressed by a bitline 533 and an inverse bitline 534 of a second bitline pair 535 and a second wordline 540.

The third inverter pair 505 is associated with a third passgate transistor pair 514 that includes a first passgate transistor 519 and a second passgate transistor 520. The first passgate transistor 519 is connected between a bitline connection 527 and an input of the first inverter 510 of the third inverter pair 505 and the second passgate transistor 520 is connected between an inverse bitline connection 528 and an input of the second inverter 511 of the third inverter pair 505. Gate electrodes of the passgate transistors 519, 520 are connected to a wordline connection 529, which can be provided in the form of two separate electrical contacts, as schematically shown in FIG. 5. The bitline connection 527, the inverse bitline connection 528 and the wordline connection 529 provide a third read/write port of the memory cell 501 that can be addressed by means of a bitline 536 and an inverse bitline 537 of a third bitline pair 535 and a third wordline 541. Reading a bit of data from the memory cell 501 and writing a bit of data to the memory cell 501 can be performed as described above with reference to FIGS. 2 and 3, wherein read and write operations at different read/write ports can be performed simultaneously.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A memory cell, comprising:
an inverter loop comprising a plurality of inverter pairs connected in a loop, wherein an output of each inverter pair is connected to an input of a next inverter pair in said loop;
each inverter pair comprising a first inverter and a second inverter, an input of said first inverter providing the input of said inverter pair, an output of said second inverter providing the output of said inverter pair, an output of said first inverter being connected to an input of said second inverter; and
a plurality of passgate transistor pairs, each inverter pair being associated with one of said plurality of passgate transistor pairs, each passgate transistor pair comprising a first passgate transistor connected to the input of said first inverter of said inverter pair associated with said passgate transistor pair and a second passgate transistor connected to the input of said second inverter of said inverter pair associated with said passgate transistor pair.

2. The memory cell of claim 1, wherein said memory cell comprises a plurality of read/write ports, each read/write port comprising a bitline connection, an inverse bitline connection and a wordline connection, each read/write port being associated with one of said passgate transistor pairs;
wherein said first passgate transistor of each passgate transistor pair is connected between said bitline connection of said read/write port associated with said passgate transistor pair and the input of said first inverter of said inverter pair associated with said passgate transistor pair;
wherein said second passgate transistor of each passgate transistor pair is connected between said inverse bitline connection of said read/write port associated with said passgate transistor pair and the input of said second inverter of said inverter pair associated with said passgate transistor pair; and
wherein a gate electrode of said first passgate transistor and a gate electrode of said second passgate transistor of each passgate transistor pair are connected to said wordline connection of said read/write port associated with said passgate transistor pair.

3. The memory cell of claim 2, wherein said plurality of inverter pairs provides an electrical insulation between each of said bitline connections and said inverse bitline connections of said plurality of read/write ports when the passgate transistors of more than one of said passgate transistor pairs are in an electrically conductive on-state.

4. The memory cell of claim 3, wherein each of said inverters comprises a pull-up transistor and a pull-down transistor, wherein the input of said inverter is connected to a gate electrode of said pull-up transistor and a gate electrode of said pull-down transistor, and the output of said inverter is connected to a drain region of said pull-up transistor and a drain region of said pull-down transistor.

5. The memory cell of claim 4, wherein said memory cell is a two-port memory cell, said plurality of read/write ports is formed by two read/write ports, said plurality of inverter pairs is formed by two inverter pairs and said plurality of passgate transistor pairs is formed by two passgate transistor pairs.

6. The memory cell of claim 4, wherein said memory cell is a three-port memory cell, said plurality of read/write ports is formed by three read/write ports, said plurality of inverter pairs is formed by three inverter pairs and said plurality of passgate transistor pairs is formed by three passgate transistor pairs.

7. The memory cell of claim 4, wherein said memory cell is a four-port memory cell, said plurality of read/write ports is formed by four read/write ports, said plurality of inverter pairs is formed by four inverter pairs and said plurality of passgate transistor pairs is formed by four passgate transistor pairs.

8. A memory device, comprising:
a plurality of memory cells, each memory cell comprising:
an inverter loop comprising a plurality of inverter pairs connected in a loop, wherein an output of each inverter pair is connected to an input of a next inverter pair in said loop;
each inverter pair comprising a first inverter and a second inverter, an input of said first inverter providing the input of said inverter pair, an output of said second inverter providing the output of said inverter pair, an output of said first inverter being connected to an input of said second inverter;
a plurality of passgate transistor pairs, each inverter pair being associated with one of said plurality of passgate transistor pairs, each passgate transistor pair comprising a first passgate transistor and a second passgate transistor;
the memory device further comprising:
a plurality of wordlines, wherein, for each memory cell, each passgate transistor pair of the memory cell is associated with one of said wordlines, and wherein, for each passgate transistor pair, a gate electrode of said first passgate transistor and a gate electrode of said second passgate transistor are connected to the wordline associated with said passgate transistor pair; and
a plurality of bitline pairs, each bitline pair comprising a bitline and an inverse bitline, wherein, for each memory cell, each passgate transistor pair is associated with one of said bitline pairs, wherein, for each passgate transistor pair, said first passgate transistor is connected between said bitline of the bitline pair associated with said passgate transistor pair and the input of the first inverter of said inverter pair associated with said passgate transistor pair and said second passgate transistor is connected between said inverse bitline of the bitline pair associated with said passgate transistor pair and the input of said second inverter of the inverter pair associated with said passgate transistor pair.

9. The memory device of claim 8, wherein said plurality of memory cells forms an array of memory cells comprising a plurality of rows and a plurality of columns.

10. The memory device of claim 9, wherein each of said plurality of memory cells provides a same number of read/write ports, wherein a number of said plurality of inverter pairs in each memory cell and a number of said plurality of passgate transistor pairs in each memory cell corresponds to the number of read/write ports.

11. The memory device of claim 10, wherein a respective subset of said plurality of wordlines is associated with each of said rows of said array of memory cells and a respective subset of said plurality of bitline pairs is associated with each of said columns of said array of memory cells, wherein a number of wordlines in each of the subsets of said plurality of wordlines corresponds to the number of read/write ports and wherein a number of bitline pairs in each of the subsets of said plurality of bitline pairs corresponds to the number of read/write ports.

12. The memory device of claim 11, wherein, for each of said plurality of memory cells, the plurality of inverter pairs of said memory cell provides an electrical insulation between each of said bitlines and inverse bitlines of said bitline pairs associated with said passgate transistor pairs of said memory cell when the passgate transistors of more than one of said passgate transistor pairs of said memory cell are in an electrically conductive on-state.

13. The memory device of claim 12, wherein each of said inverters comprises a pull-up transistor and a pull-down transistor, wherein the input of said inverter is connected to a gate electrode of said pull-up transistor and a gate electrode of said pull-down transistor, and the output of said inverter is connected to a drain region of said pull-up transistor and a drain region of said pull-down transistor.

14. The memory device of claim 13, wherein the number of read/write ports is two.

15. The memory device of claim 13, wherein the number of read/write ports is three.

16. The memory device of claim 13, wherein the number of read/write ports is four.

17. A method, comprising:
providing a memory device, said memory device comprising a memory cell, said memory cell comprising:
an inverter loop comprising a plurality of inverter pairs connected in a loop, wherein an output of each inverter pair is connected to an input of a next inverter pair in said loop;
each inverter pair comprising a first inverter and a second inverter, an input of said first inverter providing the input of said inverter pair, an output of said second inverter providing the output of said inverter pair, an output of said first inverter being connected to an input of said second inverter; and
a plurality of passgate transistor pairs, each inverter pair being associated with one of said plurality of passgate transistor pairs, each passgate transistor pair comprising a first passgate transistor and a second passgate transistor;
said memory device further comprising:
a plurality of wordlines, each of said wordlines being associated with one of said passgate transistor pairs, wherein, for each passgate transistor pair, a gate electrode of said first passgate transistor and a gate electrode of said second passgate transistor are connected to said wordline associated with said passgate transistor pair;
a plurality of bitline pairs, each bitline pair comprising a bitline and an inverse bitline, each of said bitline pairs being associated with one of said passgate transistor pairs, wherein, for each passgate transistor pair, said first passgate transistor is connected between said bitline of said bitline pair associated with said passgate transistor pair and the input of said first inverter of said inverter pair associated with said passgate transistor pair and said second passgate transistor is connected between said inverse bitline of said bitline pair associated with said passgate transistor pair and the input of said second inverter of said inverter pair associated with said passgate transistor pair;
said method further comprising:
performing a read operation at said memory cell, said read operation comprising:
applying a passgate transistor turn-on voltage to a first wordline of said plurality of wordlines and measuring a voltage difference between the bitline and the inverse bitline of a first bitline pair of said plurality of bitline pairs, wherein said first wordline and said first bitline pair are associated with a first passgate transistor pair of said plurality of passgate transistor pairs; and
performing a write operation at said memory cell, said write operation comprising:
applying said passgate transistor turn-on voltage to a second wordline of said plurality of wordlines, applying a first write voltage representing a bit of data to the bitline of a second bitline pair of said plurality of bitline pairs and applying a second write voltage representing an inverse of the bit of data to said inverse bitline of said second bitline pair, said second wordline and said second bitline pair being associated with a second passgate transistor pair of said plurality of passgate transistor pairs.

18. The method of claim 17, wherein a duration of said read operation at least partially overlaps a duration of said write operation.

19. The method of claim 18, wherein said read operation and said write operation are performed substantially simultaneously.

20. The method of claim 19, wherein said plurality of inverter pairs of said memory cell provides an electrical insulation between each of said bitlines and inverse bitlines of said plurality of bitline pairs during said read operation and said write operation.
